(19) United States
(12) Patent Application Publication
(10) Pub. No.: US 2011/0214925 A1
(43) Pub. Date: Sep. 8, 2011

(54) Touch Sensor Device

(76) Inventor: Chao Kuo Hsieh, Taipei County (TW)

(21) Appl. No.: 12/715,399

(22) Filed: Mar. 2, 2010

(51) Int. Cl. G06F 3/046; H03K 17/94; G06F 3/041

(52) U.S. Cl. 178/18.07; 341/20; 345/173

(57) ABSTRACT

A touch sensor device with increased transmittance, increased sensitivity and decreased thickness is disclosed. The touch sensor device includes a substrate. The substrate, from bottom to top, sequentially includes a bottom conductive layer, a bottom insulation layer, a top conductive layer, an electrode layer, a top insulation layer and a substrate material layer. The bottom conductive layer can shield external electromagnetic interference and act as a ground. The bottom insulation layer is provided with an insulation effect. The top conductive layer is used for sensing a touch operation to generate a sensor signal. The electrode layer includes a plurality of first electrode lines, a barrier layer and a plurality of second electrode lines. The top insulation layer is provided with an effect for preventing electrostatic discharge. The substrate material layer is used for protecting the touch sensor device.

### BACKGROUND OF THE INVENTION

1. Field of the Invention

The present invention is related to a structure of a touch sensor device, and more particularly, to a touch sensor device with increased transmittance, increased sensitivity and decreased thickness which can be manufactured with reduced cost and simplified process.

2. The Prior Arts

Touch sensor devices have been applied widely as user interfaces in various electronic devices, such as cellular phones, tablet computers, personal digital assistants (PDA), and digital home appliances. When in use, users may touch the surface of the touch sensor device by a finger or a touch pen to operate the touch sensor device.

Conventional touch sensor devices are generally formed by bonding a cover lens and a touch panel with an optical clear adhesive (OCA). The touch panel, from bottom to top, sequentially includes a substrate, a bottom insulation layer, a lower conductive layer, a top insulation layer, an electrode layer and an upper conductive layer.

FIG. 1 is an exploded cross-sectional view of a conventional touch sensor device 10. The touch sensor device 10 sequentially includes a cover lens 1, an optical adhesive layer 2 and a touch panel 3. The touch panel 3, from bottom to top, sequentially comprises a substrate 31, a bottom insulation layer 32, a lower conductive layer 33, a top insulation layer 34, an electrode layer 35 and an upper conductive layer 36. The optical adhesive layer 2 is used for bonding the touch penal 3 to the cover lens 1. The cover lens 1 is used for protecting the touch penal 3.

As shown in FIG. 1, the conventional touch sensor device 10 needs the optical adhesive 2 to attach the two layers, namely the cover lens 1 and the touch panel 3. As a result, when the touch sensor device 10 is assembled on a display device to form a touch sensor display device, the light from the display device has to pass through multiple layers of the touch sensor device 10. Therefore, there are disadvantages of poor transmittance and thick structure.

At the same time, because the conventional touch sensor device 10 is a multi-layer structure, it is equivalent to a plurality of capacitors connected in series. It results that the capacitance of the touch sensor device 10 is decreased. Thus, the sensitivity of the touch sensor device 10 is decreased accordingly. Further, because using the optical adhesive 2 to bond the touch penal 3 with the cover lens 1, bubbles are likely to be formed during attaching the touch penal 3 with the cover lens 1, which degrades the performance of the touch sensor device 10. Moreover, because it needs multiple components for forming the touch sensor device 10, high manufacturing cost and complicated manufacturing process become an issue.

### SUMMARY OF THE INVENTION

As a solution to the disadvantages described above, a primary objective of the present invention is to provide a touch sensor device with increased transmittance, increased sensitivity and decreased thickness which has lower manufacturing cost and simplified manufacturing process.

A touch sensor device according to the present invention uses fewer components to achieve the objective. The touch sensor device according to the present invention comprises a substrate. The substrate, from bottom to top, sequentially includes a bottom conductive layer, a bottom insulation layer, a top conductive layer, an electrode layer, a top insulation layer and a substrate material layer. The bottom conductive layer has a shielding effect for shielding external electromagnetic interference and acts as a ground. The bottom insulation layer is disposed on the bottom conductive layer and is provided with an insulation effect. The top conductive layer is disposed on the bottom insulation layer and is used for sensing a touch operation to generate a sensor signal. The electrode layer is disposed on the top conductive layer, and includes a plurality of first electrode lines, a barrier layer and a plurality of second electrode lines. The first electrode lines and the second electrode lines are used for receiving the sensor signal to determine the position of the touch operation. The top insulation layer is disposed on the electrode layer and is provided with an effect for preventing electrostatic discharge. The substrate material layer is disposed on the top insulation layer and is used for protecting the touch sensor device.

The substrate according to the present invention directly combines the touch panel and the cover lens of the conventional touch sensor device to form a single layer in structure. Therefore, it does not need to employ the optical adhesive layer of the conventional touch sensor device.

Because the touch sensor device according to the present invention has a special single-layer structure, the capacitance of the touch sensor device according to the present invention is greater than that of the conventional touch sensor device. Thus the sensitivity of the touch sensor device according to the present invention is increased accordingly.

Since fewer components are used for forming the touch sensor device of the present invention, manufacturing cost is reduced, thickness is decreased, manufacturing process is simplified, transmittance of the touch sensor device is increased, and at the same time the sensitivity of the touch sensor device as a whole is increased.

### BRIEF DESCRIPTION OF THE DRAWINGS

The present invention will be apparent to those skilled in the art by reading the following detailed description of a preferred embodiment thereof, with reference to the attached drawings, in which:

FIG. 1 is an exploded cross-sectional view showing a conventional touch sensor device;

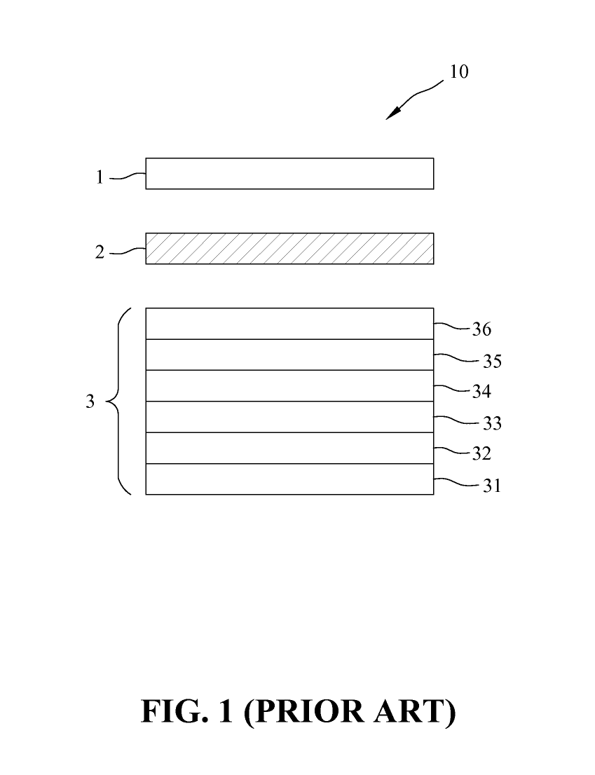

FIG. 2 is a cross-sectional view showing a touch sensor device according to an embodiment of the present invention;

FIG. 3 is a top view showing an electrode layer according to the present invention;

FIG. 4 is a partial detailed view showing first electrode lines shown in FIG. 3;

FIG. 5 is a partial detailed view showing the electrode layer of FIG. 3; and

FIG. 6 is a partial detailed view showing a top conductive layer of the touch sensor device according to the present invention.

### DETAILED DESCRIPTION OF THE PREFERRED EMBODIMENT

The accompanying drawings are included to provide a further understanding of the present invention, and are incorporated in and constitute a part of this specification. The drawings illustrate embodiments of the present invention and, together with the description, serve to explain the principles of the present invention.

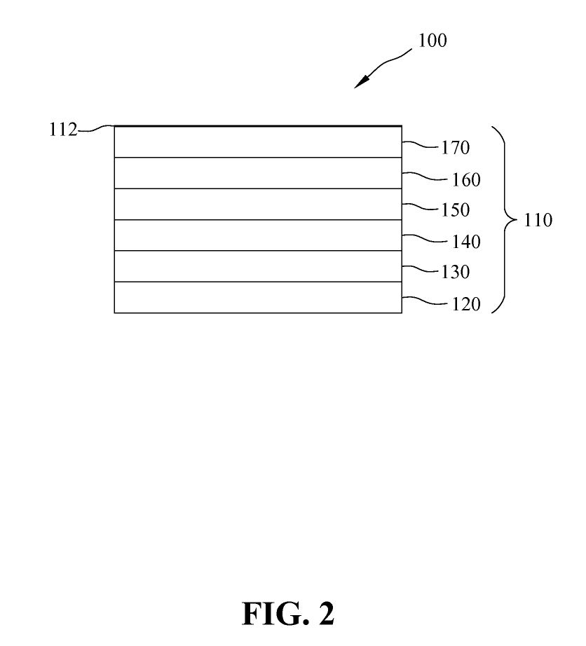

Referring to FIG. 2, a touch sensor device 100 according to an embodiment of the present invention includes a substrate 110. The substrate 110, from bottom to top, sequentially includes a bottom conductive layer 120, a bottom insulation layer 130, a top conductive layer 140, an electrode layer 150, a top insulation layer 160 and a substrate material layer 170.

The substrate 110 has an upper surface 112 for receiving a touch operation. The substrate 110 comprises one of glass and polymethylmethacrylate (PMMA).

The bottom conductive layer 120 is provided with a shielding effect for shielding any possible external electromagnetic interference, such as other application modules underneath, to maintain an interference-free working environment for the touch sensor device 100. At the same time, the bottom conductive layer 120 is acting as a ground of the touch sensor device 100. The bottom conductive layer 120 comprises at least one of indium tin oxide (ITO) and tin dioxide (SnO₂).

The bottom insulation layer 130 is disposed on the bottom conductive layer 120 and is provided with an insulation effect. The bottom insulation layer 130 comprises at least one of silicon dioxide (SiO₂) and aluminum oxide (Al₂O₃).

The top conductive layer 140 is disposed on the bottom insulation layer 130 and is used for sensing the touch operation to generate a sensor signal. The top conductive layer 140 comprises indium tin oxide.

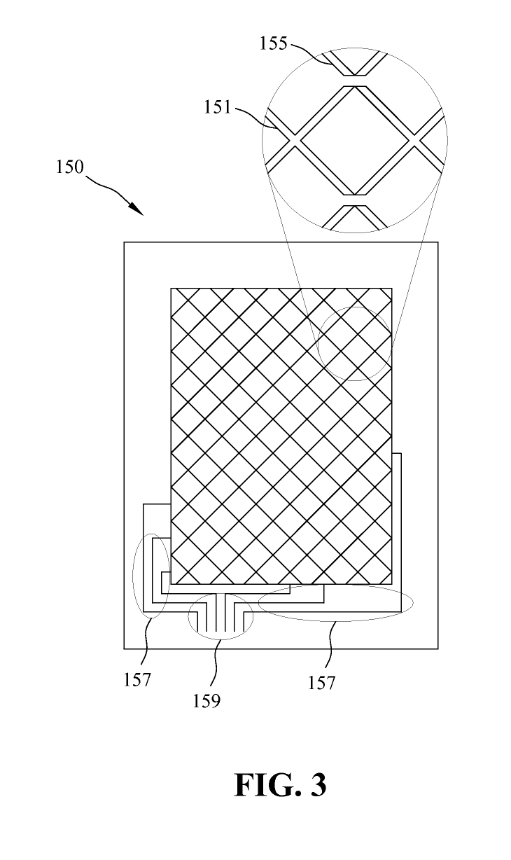

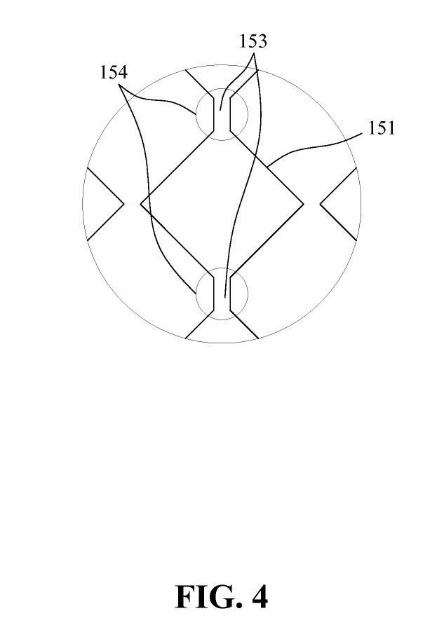

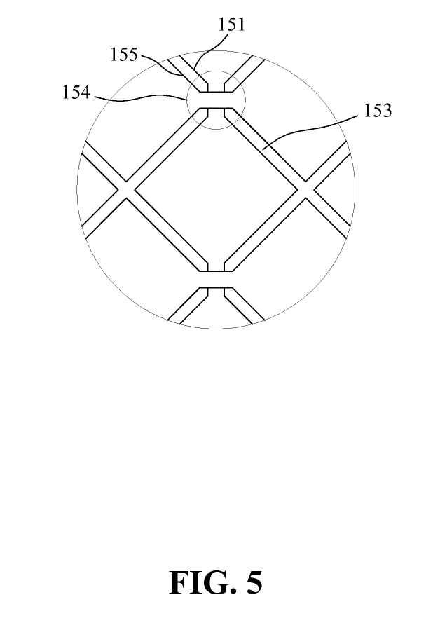

Referring to FIGS. 3 to 5, the electrode layer 150 is disposed on the top conductive layer 140 and comprises a plurality of first electrode lines 151, a barrier layer 153 and a plurality of second electrode lines 155. The first electrode lines 151 have a first direction and the second electrode lines 155 have a second direction. The first direction and the second direction may be any direction and the first direction is different from the second direction. The first direction according to the embodiment is in the vertical direction as shown in FIG. 4 and the second direction is in the horizontal direction. The first electrode lines 151 and the second electrode lines 155 are used for receiving the sensor signal generated by the top conductive layer 140 to determine the position of the touch operation. As shown in FIG. 3, the first electrode lines 151 and the second electrode lines 155 extend to the edges respectively, and converge to form a peripheral region 157. The peripheral region 157 further converges to form a terminal region 159 for electrically connecting the touch sensor device 100 to other application modules. Referring to FIGS. 4 and 5, the barrier layer 153 is disposed between the first electrode lines 151 and the second electrode lines 155 adjacent to the first electrode lines 151. The barrier layer 153 is also disposed at an overlap region 154, where the first electrode lines 151 cross over the second electrode lines 155, to prevent electrical shortcuts. The first electrode lines 151 and the second electrode lines 155 comprise molybdenum and aluminum, and the barrier layer 153 comprises clear insulation adhesive.

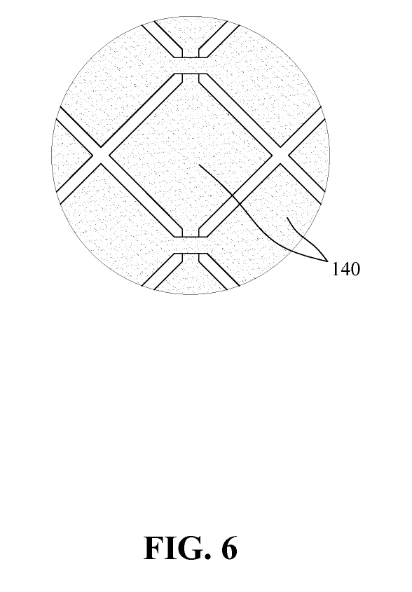

Referring to FIG. 6, the top conductive layer 140 is disposed under the electrode layer 150 and is disposed at the blocks defined by the first electrode lines 151 and the block defined by the second electrode lines 155.

Referring to FIG. 2, the top insulation layer 160 is disposed on the electrode layer 150 and is provided with an effect for preventing electrostatic discharge (ESD). The top insulation layer 160 comprises silicon dioxide.

The substrate material layer 170 is disposed on the top insulation layer 160 and acts as a part of the substrate 110 for protecting the touch sensor device 100 according to the present invention, allowing the touch sensor device 100 to be free of external interference. The substrate material layer 170 comprises one of glass and polymethylmethacrylate.

When in use, the user performs a touch operation by touching the upper surface 112 of the touch sensor device with conductive articles such as fingers or touch pens. The conductive article carries a part of electrical current and the sensor signal is then generated. The position of the touch operation then may be calculated by the electrode layer 150 upon the sensor signal.

The touch sensor device 100 according to the present invention may further be coated with a surface insulation layer (not shown in the figures) on the upper surface 112 for purposes of anti-dirt and anti-fingerprint, etc. to provide the user a better access to the touch sensor device 100. The surface insulation layer comprises aluminum oxide.

The touch sensor device 100 according to the present invention may further comprise a shielding layer (not shown in the figures) disposed under the top insulation layer 160 and on the electrode layer 150. The shielding layer is a dark material and is used for shielding the peripheral region 157.

An operation pattern layer (not shown in the figures) can be directly disposed under the bottom conductive layer 120 in coordination with the functions of the touch sensor device 100, to better assist the user to perform operations on the touch sensor device 100 of the present invention.

Since fewer components are used for forming the touch sensor device of the present invention, manufacturing cost is reduced, manufacturing process is simplified and transmittance of the touch sensor device is increased. Further, there is no need to employ the optical adhesive layer of the conventional touch sensor device in the present invention. Thus not only the manufacturing cost and manufacturing process are reduced and simplified, but also the possibility of the formation of the bubbles during attachment is minimized. Moreover, a greater capacitance as a whole compared to the conventional touch sensor device can be generated when the user touches the touch sensor device according to the present invention due to the unique single structure of the touch sensor device of the present invention, and thus the sensitivity of the touch sensor device as a whole is increased accordingly.

The touch sensor device according to the present invention may be applied to fingerprint readers, gateway monitoring systems and security surveillance monitors where the touch sensor devices are applicable.

Further, the touch sensor device 100 of the present invention may be applied in combination with display devices to form touch sensor display devices. The touch sensor display devices can be applied in computers, mobile phones, cellular phones, digital media players, personal digital assistants, electronic books where the touch sensor display devices are applicable.

Although the present invention has been described with reference to the preferred embodiments thereof, it is apparent to those skilled in the art that a variety of modifications and changes may be made without departing from the scope of the present invention which is intended to be defined by the appended claims.

What is claimed is:

1. A touch sensor device, comprising:
a substrate having an upper surface for receiving a touch operation, the substrate comprising:
a bottom conductive layer having a shielding effect for shielding external electromagnetic interference and acting as a ground;
a bottom insulation layer disposed on the bottom conductive layer and having an insulation effect;
a top conductive layer disposed on the bottom insulation layer for sensing the touch operation to generate a sensor signal;
an electrode layer disposed on the top conductive layer and including a plurality of first electrode lines, a barrier layer and a plurality of second electrode lines, wherein the first electrode lines and the second electrode lines are used for receiving the sensor signal to determine a position of the touch operation;
a top insulation layer disposed on the electrode layer and provided with an effect for preventing electrostatic discharge; and
a substrate material layer disposed on the top insulation layer for protecting the touch sensor device.

2. The touch sensor device according to claim 1, wherein the first electrode lines and the second electrode lines extend to an edge respectively and converge to form a peripheral region, the peripheral region further converges to form a terminal region for electrically connecting the touch sensor device to other application modules; the barrier layer is disposed between the first electrode lines and the second electrode lines adjacent to the first electrode lines, and the barrier layer is also disposed at an overlap region where the first electrode lines cross over the second electrode lines to prevent electrical shortcuts, wherein the first electrode lines have a first direction and the second electrode lines have a second direction, and the first direction is different from the second direction.

3. The touch sensor device according to claim 1, wherein the substrate comprises one of glass and polymethylmethacrylate.

4. The touch sensor device according to claim 1, wherein the bottom conductive layer comprises at least one of indium tin oxide and tin dioxide.

5. The touch sensor device according to claim 1, wherein the bottom insulation layer comprises at least one of silicon dioxide and aluminum oxide.

6. The touch sensor device according to claim 1, wherein the top conductive layer comprises indium tin oxide.

7. The touch sensor device according to claim 1, wherein the first electrode lines and the second electrode lines comprise molybdenum and aluminum.

8. The touch sensor device according to claim 1, wherein the barrier layer comprises clear insulation adhesive.

9. The touch sensor device according to claim 1, wherein the top insulation layer comprises silicon dioxide.

10. The touch sensor device according to claim 1, wherein the substrate material layer comprises one of glass and polymethylmethacrylate.

11. The touch sensor device according to claim 1, further comprising a surface insulation layer disposed on the upper surface, wherein the surface insulation layer comprises aluminum oxide.

12. The touch sensor device according to claim 1, further comprising a shielding layer disposed under the top insulation layer and on the electrode layer for shielding the peripheral region.

13. The touch sensor device according to claim 1, further comprising an operation pattern layer disposed under the bottom conductive layer.

14. The touch sensor device according to claim 1, wherein the touch operation is performed by touching the upper surface with a conductive article, the conductive article comprise at least one of fingers and touch pens.
